(19) United States
(12) Patent Application Publication
(10) Pub. No.: US 2024/0330224 A1
(43) Pub. Date: Oct. 3, 2024

(54) Method and apparatus for timing training on an LVDS interface

(71) Applicant: SHENZHEN PANGO MICROSYSTEMS CO., LTD, Shenzhen (CN)

(72) Inventors: Shang GAO, Shenzhen (CN); Wei DING, Shenzhen (CN); Rui YAO, Shenzhen (CN); Xuelei XUAN, Shenzhen (CN)

(21) Appl. No.: 18/620,179

(22) Filed: Mar. 28, 2024

(30) Foreign Application Priority Data
Mar. 28, 2023 (CN) 202310368747.1

(51) Int. Cl. G06F 13/40

(52) U.S. Cl. CPC G06F 13/405

(57) ABSTRACT

A method and apparatus for timing training on an LVDS interface includes sampling by using the second parallel data as reference data and the first parallel data as scanning data, the first delay stage is obtained; sampling by using the first parallel data as reference data and the second parallel data as scanning data, and setting the initial delay stage of the second parallel data as the first delay stage, the second delay stage is obtained, and setting the sum of the first delay stage and half of the delay stage difference as the delay stage of the first parallel data, then receiving the LVDS differential data. The method is capable of handling the impact of OCV and asymmetry in signal slopes on the effective data window, avoiding glitches, and reducing the requirements for delay chain design.

The present disclosure relates to the technical field of FPGA (Field Programmable Gate Array), especially relates to a method and apparatus for timing training on an LVDS interface.

### BACKGROUND

For LVDS (Low Voltage Differential Signaling) interface of FPGA (Field Programmable Gate Array), it is common to adjust the phase of the sampling clock or the serial data by means of changing the stage count of the delay chain, thereby ensuring the relationship between the serial data and the sampling clock. However, when switching the stage count of the delay chain, it is prone to introduce glitches in the data stream.

On the same wafer, chips in different regions may experience varying errors due to external and manufacturing conditions. Consequently, on the same wafer, the transistors in certain regions on chips may exhibit overall speeds that are faster or slower. At the same time, within different regions on the same chip, further differences may arise due to the aforementioned factors, that is OCV (on-chip variation).

When performing timing training for the LVDS interface receiver, it is common to determine the sampling position by transmitting a certain period of training data sequence and to determine the center position of the effective data window by repeatedly comparing fixed training sequences. However, existing timing training methods cannot handle the adverse effects of chip OCV variations on window accuracy. For example, if a delay unit in a delay chain is designed to have a delay value of 10 ps, With the same circuit, the actual delay in different parts of the chip may be 9.5 ps or 10.5 ps. After cascading delay chains, the actual delay differences may be even greater. Temperature, voltage, and process variations can also affect the delay values of delay units. Existing timing training methods cannot avoid the impact of the difference between the rise slope and the fall slope of data on the effective data window, that is, it is impossible to avoid the impact of the asymmetry between the P data and N data of LVDS signals on the effective data window. As shown in FIG. 1, this is a schematic diagram illustrating the impact of asymmetry in rise and fall times of OCV and LVDS signal P and N data on the data window.

### SUMMARY

The present disclosure provides a method and apparatus for timing training on an LVDS interface. It solves the problems of introducing glitches in the data stream caused by delay chain stage switching, requiring the sending of training sequences for interface timing training, the adverse impact of chip OCV differences on window accuracy and the impact of LVDS signal P data and N data asymmetry on the effective data window.

A method for timing training on an LVDS interface comprises:
S1 Inputting the P-end of the LVDS differential data signal into a first delay chain, and converting them into first parallel data through serial-to-parallel conversion; inputting the N-end of the LVDS differential data signal into a second delay chain, and converting them into second parallel data through serial-to-parallel conversion;
S2 Sampling by using the second parallel data as reference data and the first parallel data as scanning data, and collecting the relative position between the sampling position corresponding to the current delay stage and the center of the scanning data window, when the sampling position corresponding to the current delay stage is located at the center of the scanning data window, the current delay stage is recorded as the first delay stage;
S3 Sampling by using the first parallel data as reference data and the second parallel data as scanning data, and setting the initial delay stage of the second parallel data as the first delay stage, collecting the relative position between the sampling position corresponding to the current delay stage and the center of the scanning data window, when the sampling position corresponding to the current delay stage is located at the center of the scanning data window, the current first delay stage is recorded as the second delay stage;
S4 Obtaining the delay stage difference according to the first delay stage and the second delay stage, and setting the sum of the first delay stage and half of the delay stage difference as the delay stage of the first parallel data, receiving the LVDS differential data by using the second parallel data as scanning data.

In some examples, S2 comprises:
S21 Sampling by using the second parallel data as reference data after setting the initial delay stage of the first parallel data, and collecting the relative position corresponding to the initial delay stage, wherein the initial delay stage is less than the total delay stage of the first delay chain;
S22 When the sampling position corresponding to the current initial delay stage is offset to the left relative to the center of the first parallel data window, decreasing the current initial delay stage, and after updating the decreased initial delay stage to the initial delay stage, re-collecting the relative position;
When the sampling position corresponding to the current initial delay stage is offset to the right relative to the center of the first parallel data window, increasing the current initial delay stage, and after updating the increased initial delay stage to the initial delay stage, re-collecting the relative position;
S23 When the sampling position corresponding to the current initial delay stage is located at the center of the first parallel data window, the initial delay stage corresponding to the sampling position is taken as the first delay stage.

In some examples, S3 comprises:
S31 Scanning is conducted using the first parallel data as reference data after setting the first delay stage as the initial delay stage of the second parallel data, whilst collecting the relative position corresponding to the initial delay stage;
S32 When the sampling position corresponding to the current initial delay stage is offset to the left relative to the center of the second parallel data window, decreasing the current initial delay stage, and after updating the decreased initial delay stage to the initial delay stage, re-collecting the relative position;
When the sampling position corresponding to the current initial delay stage is offset to the right relative to the center of the first parallel data window, increasing the current initial delay stage, and after updating the increased initial delay stage to the initial delay stage, re-collecting the relative position;
S33 When the sampling position corresponding to the current initial delay stage is located at the center of the second parallel data window, the initial delay stage corresponding to the sampling position is taken as the second delay stage.

In some examples, collecting the relative position between the sampling position corresponding to the delay stage and the center of scanning data window in S2 and S3 comprises:
S51 Selecting one set of data between the first parallel data and the second parallel data as reference data, and the other set of data as scanning data, to collect data, and the current delay stage corresponding to the scanning data in both the first parallel data and the second parallel data is defined as the delay stage of the scanning data;
S52 Decreasing the current delay stage step by step, monitoring whether the reference data and the scanning data are consistent during a specific time period;
S53 If the reference data and the scanning data are consistent, and the current delay stage has not decreased to zero, repeating S52; otherwise, recording the current delay stage as the first sub-delay stage and proceeding to S54;
S54 Reloading the current delay stage;
S55 Increasing the current delay stage step by step, monitoring whether the reference data and the scanning data are consistent during a specific time period;
S56 If the reference data and the scanning are consistent, and the current delay stage has not reached the maximum delay stage value, repeating S55; otherwise, recording the current delay stage as the second sub-delay stage;
S57 Based on the current delay stage, the first sub-delay stage, and the second sub-delay stage, obtaining the first sub-delay stage difference between the current delay stage and the first sub-delay stage, and the second sub-delay stage difference between the current delay stage and the second sub-delay stage; comparison of the first sub-delay stage difference and the second sub-delay stage difference, obtaining the relative position between the sampling position corresponding to the current delay stage and the center of the scanning data window.

In some examples, S57 comprises:
S571 The difference between the current delay stage and the first sub-delay stage is defined as the first sub-delay stage difference, and the difference between the second sub-delay stage and the current delay stage is defined as the second sub-delay stage difference;
S572 If the first sub-delay stage difference is greater than the second sub-delay stage, then the current sampling position corresponding to the current delay stage is offset to the left relative to the center of the scanning data window in both the first parallel data and the second parallel data;
If the first sub-delay stage difference is less than the second sub-delay stage, then the current sampling position corresponding to the current delay stage is offset to the right relative to the center of the scanning data window in both the first parallel data and the second parallel data;
If the first sub-delay stage difference equals to the second sub-delay stage, then the current sampling position corresponding to the current delay stage is at the center of the scanning data window in both the first parallel data and the second parallel data.

In some examples, the total delay of the first delay chain and the second delay chain is greater than the width of the serial data window.

In some examples, prior to S1, further comprising:
S0 Scrambling the LVDS differential data, converting them into serial data through parallel-to-serial conversion, and inputting them into delay chain;
After S4, further comprising:
S6 Descrambling and restoring the received LVDS differential data.

In some examples, the initial delay stage is half of the total delay stage of the first delay chain.

In some examples, the smaller the delay stage difference, the smaller the discrepancy in errors on the same chip and the difference in delay stages caused by asymmetry in the P-end and N-end slopes of LVDS differential data.

An apparatus for timing training on an LVDS interface comprises:
a conversion module, which is configured for inputting the P-end of the LVDS differential data signal into the first delay chain, converting it into the first parallel data through serial-to-parallel conversion; inputting the N-end of the LVDS differential data signal into the second delay chain, converting it into the second parallel data through serial-to-parallel conversion;
a first sampling module, which is configured for sampling data with the second parallel data as reference data and the first parallel data as scanning data, and collecting the relative position between the sampling position corresponding to the delay stage and the center of the scanning data window, when the sampling position corresponding to the delay stage is located at the center of the scanning data window, recording the current delay stage as the first delay stage;
a second sampling module, which is configured for sampling data with the first parallel data as reference data and the second parallel data as scanning data, setting the initial delay stage of the second parallel data the same as the first delay stage, and collecting the relative position between the sampling position corresponding to the delay stage and the center of the scanning data window, and when the sampling position corresponding to the first delay stage is located at the center of the scanning data window, recording the current first delay stage as the second delay stage;
a data output path determination module, which is configured for obtaining the delay stage difference through the first delay stage and the second delay stage, setting the sum of the first delay stage and half of the delay stage difference as the delay stage of the first parallel data, and receiving LVDS differential data by using the second parallel data as scanning data.

The beneficial effects of the present disclosure are as follows:

The method for timing training on an LVDS interface provided by the present disclosure involves inputting the Pend of the LVDS differential data signal into the first delay chain and inputting the N-end of the LVDS differential data signal into the second delay chain. Then, sampling data is conducted using the second parallel data as reference data and the first parallel data as scanning data. When the sampling position corresponding to the current delay stage is located at the center of the scanning data window, the first delay stage is obtained. Then, sampling data is conducted using the first parallel data as reference data and the second parallel data as scanning data, with the initial delay stage of the second parallel data set to the first delay stage. When the sampling position corresponding to the current delay stage is located the center of the scanning data window, the second delay stage is obtained. The delay stage difference is obtained according to the first delay stage and the second delay stage. Finally, setting the sum of the first delay stage and half of the delay stage difference as the delay stage of the first parallel data, receiving the LVDS differential data using the second parallel data as scanning data. This method is capable of handling the impact of OCV and the asymmetry in signal slopes of the P-end and N-end of LVDS differential data on the effective data window. Additionally, it avoids introducing glitches in the data stream when switching delay chain stage, thereby reducing the design requirements of the delay chain. The apparatus for timing training on an LVDS interface provided by the present disclosure can also achieve the above effects.

### BRIEF DESCRIPTION OF THE DRAWINGS

FIG. 1 shows a schematic diagram illustrating the impact of OCV and the Rise and Fall Time Symmetry of the P data and N data of LVDS signal on the effective data window.

FIG. 2 shows a schematic diagram of the LVDS transceiver architecture applied to the timing training method for LVDS interface.

FIG. 3 shows a schematic diagram illustrating the process of a timing training method for LVDS interface.

FIG. 4 shows a schematic diagram illustrating the process of obtaining the first delay stage.

FIG. 5 shows a schematic diagram illustrating the process of obtaining the second delay stage.

FIG. 6 shows a schematic diagram illustrating the process of collecting the relative position between the sampling position corresponding to the delay stage and the center of scanning data window.

FIG. 7 shows a schematic diagram illustrating the process of another timing training method for LVDS interface.

FIG. 8 shows a block diagram of a timing training apparatus for LVDS interface.

### DETAILED DESCRIPTION

The present disclosure will be further described below with reference to the accompanying drawings and embodiments.

In the following description, for purposes of explanation and not limitation, specific details are set forth, such as specific system structures, interfaces, techniques, etc., to provide a thorough understanding of the present disclosure.

The terms “system” and “network” are often configured interchangeably. The term “and/or” is only an association relationship to describe associated objects. The term “and/or” indicates that three relationships can exist. For example, A and/or B can mean that A exists alone, A and B exist at the same time, and B exists alone. In addition, the character “/” generally indicates that the related objects are “or”. And the “multiple” means two or more.

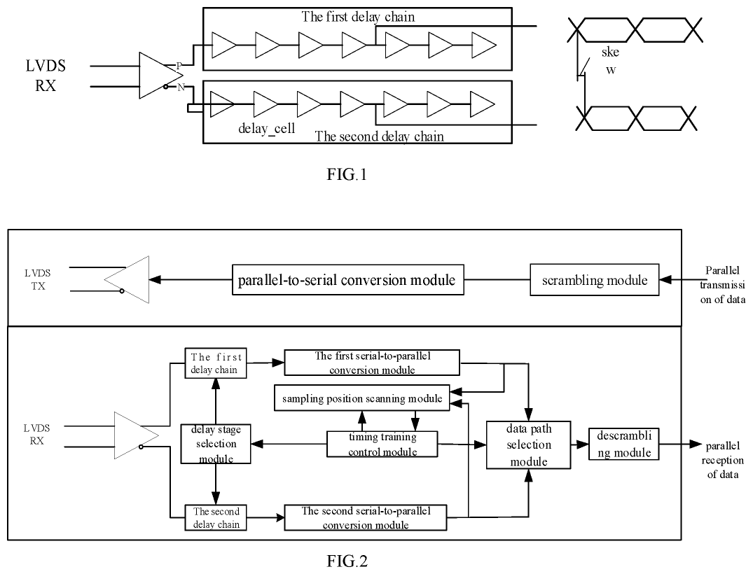

As shown in FIG. 2, it is a schematic diagram of the LVDS transceiver architecture applied to the timing training method for LVDS interface provided in an embodiment of the present invention, including the transmitter and receiver of the LVDS transceiver. The transmitter comprises a scrambling module and a parallel-to-serial conversion module, and the receiver comprises a first delay chain, a first serial-to-parallel conversion module, a second delay chain, a second serial-to-parallel conversion module, a delay stage selection module, a sampling position scanning module, a timing training control module, a data path selection module, and a descrambling module. Wherein the transmission path consisting of the first delay chain and the first serial-to-parallel conversion module is labeled as a first path, and the transmission path consisting of the second delay chain and the second serial-to-parallel conversion module is labeled as a second path. At the transmitter terminal of the LVDS transceiver, parallel data is scrambled by the scrambling module. Subsequently, the scrambled parallel data is transmitted to the serializer module, where they are converted into serial data. The serialized data stream are then transmitted at LVDS voltage stage. At the receiver terminal of the LVDS transceiver, the P-end and N-end of the LVDS differential data signal are respectively inputted into either the first path or the second path. Then they are respectively converted into parallel data with serial-to-parallel, and the current sampling position is determined by comparing the parallel data from both paths.

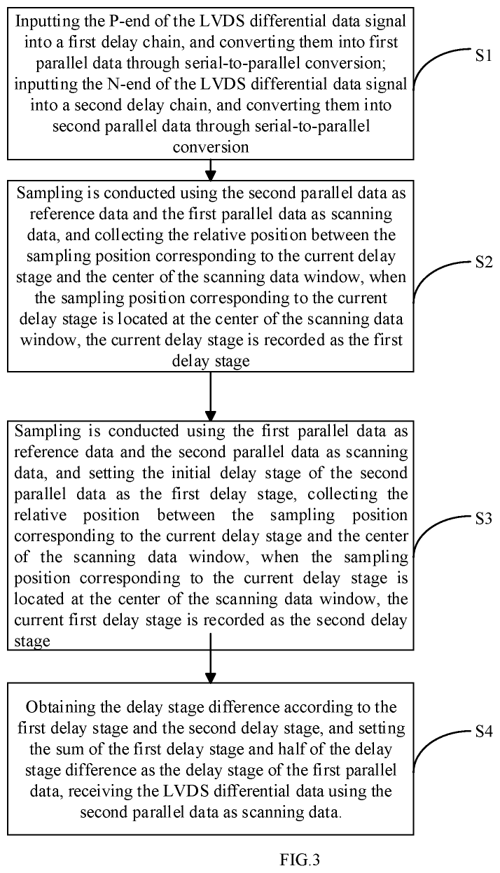

As shown in FIG. 3, it illustrates a schematic diagram illustrating the process of timing training method of for LVDS interface, applied to the receiver terminal of the LVDS transceiver shown in FIG. 2. The method comprises:
S1 Inputting the P-end of the LVDS differential data signal into a first delay chain, and converting them into first parallel data through serial-to-parallel conversion; inputting the N-end of the LVDS differential data signal into a second delay chain, and converting them into second parallel data through serial-to-parallel conversion;
S2 Sampling by using the second parallel data as reference data and the first parallel data as scanning data, and collecting the relative position between the sampling position corresponding to the current delay stage and the center of the scanning data window, when the sampling position corresponding to the current delay stage is located at the center of the scanning data window, the current delay stage is recorded as the first delay stage;
S3 Sampling by using the first parallel data as reference data and the second parallel data as scanning data, and setting the initial delay stage of the second parallel data as the first delay stage, collecting the relative position between the sampling position corresponding to the current delay stage and the center of the scanning data window, when the sampling position corresponding to the current delay stage is located at the center of the scanning data window, the current first delay stage is recorded as the second delay stage;
S4 Obtaining the delay stage difference according to the first delay stage and the second delay stage, and setting the sum of the first delay stage and half of the delay stage difference as the delay stage of the first parallel data, receiving the LVDS differential data by using the second parallel data as scanning data.

Specifically, the timing training module in FIG. 2 provides the sampling signal to the sampling position scanning module. The sampling position scanning module scans the position relationship between the sampling position and the center of the window to monitor the position relationship between the scanning sampling position and the center of the window. If the data window is offset from the center of the window, the sampling position is calibrated.

When the sampling position scanning module receives the sampling signal from the timing training module, the P-end of the LVDS differential data signal is inputted into the first delay chain in FIG. 2. Subsequently, the data outputted from the first delay chain are inputted into the first serial-to-parallel module and are converted into the first parallel data. The N-end of the LVDS differential data signal is inputted into the second delay chain in FIG. 2. Subsequently, the data outputted from the second delay chain are inputted into the second Serial-to-Parallel Module and are converted into the second parallel data. Perform timing training using the second path as the scanning path and the first path as the reference path. After setting the initial delay stage of the first delay chain (which can be set as half of the total delay stage of the first delay chain), the sampling position scanning module starts to collect the relative position between the sampling position corresponding to the initial delay stage and the center of the scanning data window. If the sampling position corresponding to the initial delay stage is located at the center of the scanning data window, the initial delay stage is recorded as the first delay stage. If the sampling position corresponding to the initial delay stage is not at the center of the scanning data window, the delay stage is adjusted based on the position result obtained by the sampling position scanning module. The adjusted delay stage is then sent to the delay stage selection module, which forwards it to the first delay chain. The sampling position scanning module continues scanning, and when the sampling position is located at the center of the scanning data window, the current delay stage is recorded as the first delay stage. Then, the timing training is conducted with the first path as the scanning path and the second path as the reference path. The initial delay stage of the second delay chain is set as the first delay stage, and the sampling position scanning module begins to collect the relative position between the sampling position corresponding to the first delay stage and the center of the scanning data window. If the sampling position corresponding to the first delay stage is located at the center of the scanning data window, the first delay stage is recorded as the second delay stage. If the sampling position corresponding to the first delay stage is not at the center of the scanning data window, then based on the position result obtained by the sampling position scanning module, the first delay stage is adjusted and sent to the delay stage selection module. The delay stage selection module sends the adjusted delay stage to the second delay chain. The sampling position scanning module continues scanning, and when the sampling position is located at the center of the scanning data window, the current delay stage is recorded as the second delay stage. Then, the delay stage difference is obtained from the first delay stage and the second delay stage. The delay stage of the first delay chain is set to the sum of the first delay stage and half of the delay stage difference by the delay stage selection module. The second path is selected as the scanning path and sent to the data path selection module to receive LVDS differential data.

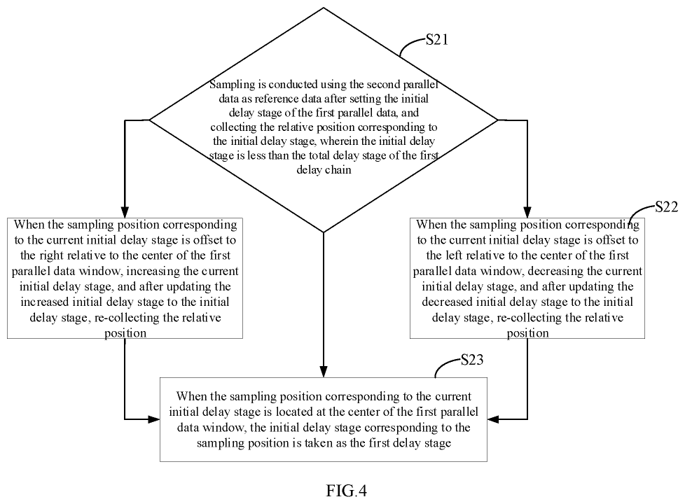

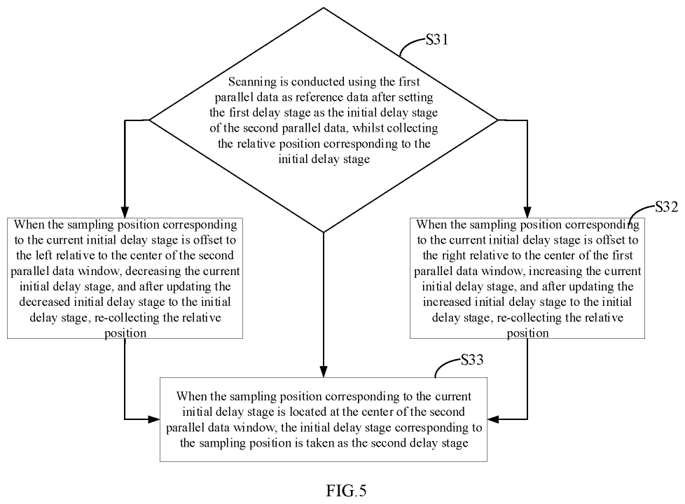

In some examples, as shown in FIG. 4, it is a schematic diagram illustrating the process of obtaining the first delay stage, S2 comprises:
S21 Sampling by using the second parallel data as reference data after setting the initial delay stage of the first parallel data, and collecting the relative position corresponding to the initial delay stage, wherein the initial delay stage is less than the total delay stage of the first delay chain;
S22 When the sampling position corresponding to the current initial delay stage is offset to the left relative to the center of the first parallel data window, decreasing the current initial delay stage, and after updating the decreased initial delay stage to the initial delay stage, re-collecting the relative position;
When the sampling position corresponding to the current initial delay stage is offset to the right relative to the center of the first parallel data window, increasing the current initial delay stage, and after updating the increased initial delay stage to the initial delay stage, re-collecting the relative position;
S23 When the sampling position corresponding to the current initial delay stage is located at the center of the first parallel data window, the initial delay stage corresponding to the sampling position is taken as the first delay stage.

Specifically, selecting the first path as the scanning path and the second path as the reference path, setting the initial delay stage of the first delay chain. The initial delay stage can be set to any number less than the total delay stage of the first delay chain. Then, the sampling position scanning module scans the relative position between the sampling position corresponding to the initial delay stage and the window center of the first parallel data. If the current sampling position corresponding to the initial delay stage is located at the window center of the first parallel data, record the current initial delay stage as the first delay stage. If the sampling position corresponding to the current initial delay stage is biased to the left relative to the window center of the first parallel data, the timing training control module decreases the initial delay stage. The decreased delay stage is then sent to the delay stage selection module, and the delay stage of the first delay chain is updated to the decreased delay stage. Subsequently, the relative position is collected between the sampling position corresponding to the current delay stage and the window center of the first parallel data. If the sampling position corresponding to the current delay stage is biased to the right relative to the window center of the first parallel data, the timing training control module increases the current initial delay stage. The increased delay stage is then sent to the delay stage selection module, and the delay stage of the first delay chain is updated to the increased delay stage. Subsequently, the relative position is collected between the sampling position corresponding to the current delay stage and the window center of the first parallel data. When the sampling position corresponding to the adjusted delay stage of the first delay chain is located at the window center of the first parallel data, the current delay stage of the first delay chain is recorded as the first delay stage.

In some examples, preferably, the initial delay stage is half of the total delay stage of the first delay chain.

In some examples, as shown in FIG. 5, it is a schematic diagram illustrating the process of obtaining the second delay stage, S3 comprises:
S31 Scanning is conducted using the first parallel data as reference data after setting the first delay stage as the initial delay stage of the second parallel data, whilst collecting the relative position corresponding to the initial delay stage;
S32 When the sampling position corresponding to the current initial delay stage is offset to the left relative to the center of the second parallel data window, decreasing the current initial delay stage, and after updating the decreased initial delay stage to the initial delay stage, re-collecting the relative position;
When the sampling position corresponding to the current initial delay stage is offset to the right relative to the center of the first parallel data window, increasing the current initial delay stage, and after updating the increased initial delay stage to the initial delay stage, re-collecting the relative position;
S33 When the sampling position corresponding to the current initial delay stage is located at the center of the second parallel data window, the initial delay stage corresponding to the sampling position is taken as the second delay stage.

Specifically, selecting the second path as the scanning path and the first path as the reference path, the initial delay stage of the second delay chain is set to the first delay stage. Then, the sampling position scanning module scans the relative position between the sampling position corresponding to the initial delay stage and the window center of the second parallel data. If the sampling position corresponding to the current first delay stage is located at the center of the window of the second parallel data, the current first delay stage is recorded as the second delay stage. If the sampling position corresponding to the current first delay stage is offset to the left relative to the window center of the second parallel data, the timing training control module decreases the initial delay stage and sends the decreased delay stage to the delay stage selection module. The delay stage of the second delay chain is updated to the decreased delay stage, and then the relative position is collected between the sampling position corresponding to the current delay stage and the window center of the second parallel data. If the sampling position corresponding to the current first delay stage is offset to the right relative to the window center of the second parallel data, the timing training control module increases the current initial delay stage and sends the increased delay stage to the delay stage selection module. The delay stage of the second delay chain is updated to the increased delay stage, and then the relative position is collected between the sampling position corresponding to the current delay stage and the window center of the second parallel data. When the sampling position corresponding to the adjusted delay stage of the second delay chain is located at the window center of the second parallel data, the current delay stage of the second delay chain is recorded as the second delay stage.

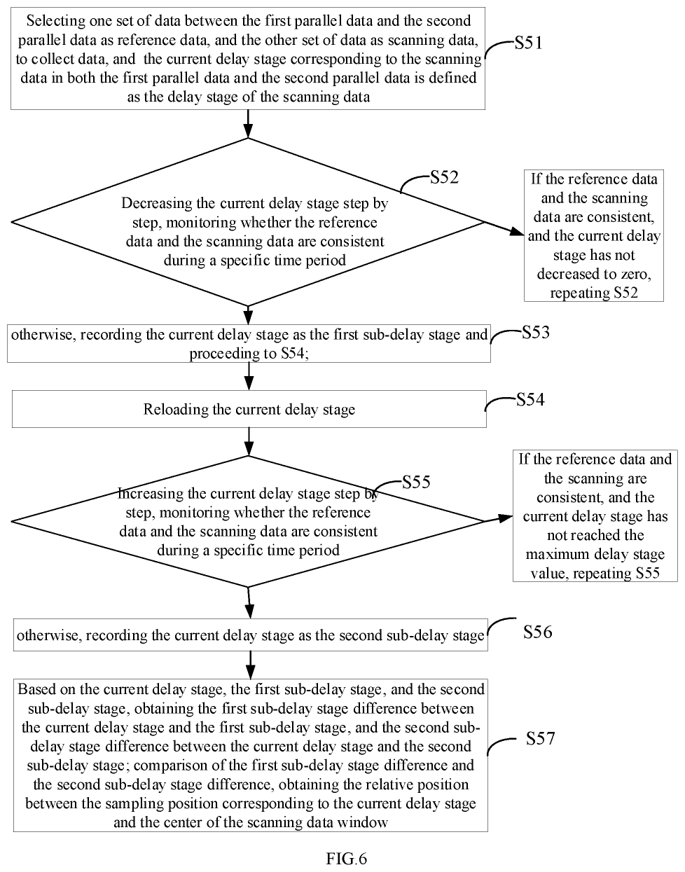

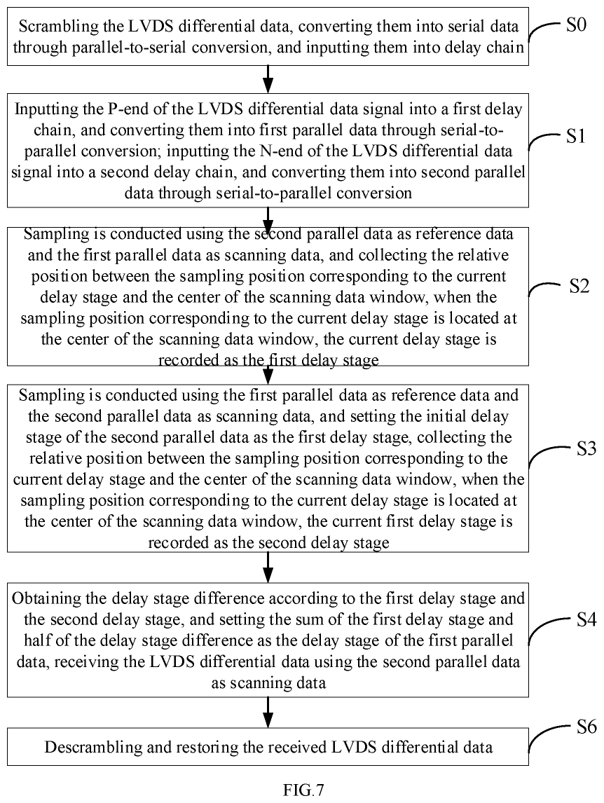

In some examples, as shown in FIG. 6, it is a schematic diagram illustrating the process of collecting the relative position between the sampling position corresponding to the delay stage and the scanning data window center. The collection of the relative position between the sampling position corresponding to the collected delay stage and the window center of the scanned data in S2 and S3 comprises:
S51 Selecting one set of data between the first parallel data and the second parallel data as reference data, and the other set of data as scanning data, to collect data, and the current delay stage corresponding to the scanning data in both the first parallel data and the second parallel data is defined as the delay stage of the scanning data;
S52 Decreasing the current delay stage step by step, monitoring whether the reference data and the scanning data are consistent during a specific time period;
S53 If the reference data and the scanning data are consistent, and the current delay stage has not decreased to zero, repeating S52; otherwise, recording the current delay stage as the first sub-delay stage and proceeding to S54;
S54 Reloading the current delay stage;
S55 Increasing the current delay stage step by step, monitoring whether the reference data and the scanning data are consistent during a specific time period;
S56 If the reference data and the scanning are consistent, and the current delay stage has not reached the maximum delay stage value, repeating S55; otherwise, recording the current delay stage as the second sub-delay stage;
S57 Based on the current delay stage, the first sub-delay stage, and the second sub-delay stage, obtaining the first sub-delay stage difference between the current delay stage and the first sub-delay stage, and the second sub-delay stage difference between the current delay stage and the second sub-delay stage; comparison of the first sub-delay stage difference and the second sub-delay stage difference, obtaining the relative position between the sampling position corresponding to the current delay stage and the center of the scanning data window.

Specifically, when the timing training control module sends a sampling signal to the sampling position scanning module, the sampling position scanning module obtains the current delay stage corresponding to the scanning path in either the first delay chain or the second delay chain determined by the timing training control module. Then, one set of data from the first delay chain or the second delay chain is selected as the reference data, and the remaining set as the scanning data. Subsequently, the delay stage of the selected scanning data is set to the current delay stage corresponding to the scanning path in the first delay chain and the second delay chain determined by the timing training control module. Then, the current delay stage is decreased step by step, and the data consistency between the reference data and the scanning data is monitored within a specific time period. If they are consistent and the current delay stage has not been decremented to zero, the current delay stage continues to be decreased. If they are not consistent, the current delay stage is recorded as the first sub-delay stage, and the current delay stage is reloaded. Subsequently, the current delay stage is increased incrementally, and the data consistency between the reference data and the scanning data is monitored within a specific time period. If they are consistent and the current delay stage has not reached the maximum delay stage, the current delay stage continues to be increased. If they are not consistent, the current delay stage is recorded as the second sub-delay stage. Then, based on the current delay stage, the first sub-delay stage, and the second sub-delay stage, the relative position between the current delay stage and the scanning data window center is obtained.

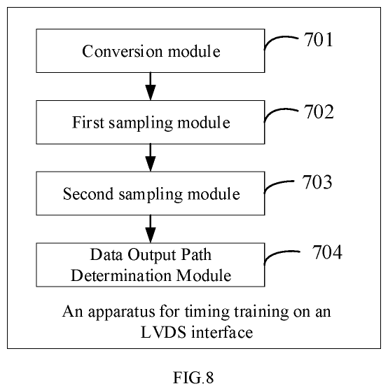

In some examples, as shown in FIG. 7, it is a schematic diagram illustrating the process of another timing training method for LVDS interface, S57 comprises:
S571 The difference between the current delay stage and the first sub-delay stage is defined as the first sub-delay stage difference, and the difference between the second sub-delay stage and the current delay stage is defined as the second sub-delay stage difference;
S572 If the first sub-delay stage difference is greater than the second sub-delay stage, then the current sampling position corresponding to the current delay stage is offset to the left relative to the center of the scanning data window in both the first parallel data and the second parallel data;
If the first sub-delay stage difference is less than the second sub-delay stage, then the current sampling position corresponding to the current delay stage is offset to the right relative to the center of the scanning data window in both the first parallel data and the second parallel data;
If the first sub-delay stage difference equals to the second sub-delay stage, then the current sampling position corresponding to the current delay stage is at the center of the scanning data window in both the first parallel data and the second parallel data.

Specifically, the current delay stage is recorded as “step0”, the first sub-delay stage as “step1”, and the second sub-delay stage as “step2”. If “step0−step1” is greater than “step2-step0”, then the sampling position corresponding to “step0” is offset to the left relative to the sampling data window center of both the first parallel data and the second parallel data. If “step0−step1” is less than “step2−step0”, then the sampling position corresponding to “step0” is offset to the right relative to the sampling data window center of both the first parallel data and the second parallel data. If “step0−step1” equals “step2−step0”, then the sampling position corresponding to “step0” is located at the sampling data window center of both the first parallel data and the second parallel data.

In some examples, the total delay of the first delay chain and the second delay chain is greater than the width of the serial data window.

In some examples, as shown in FIG. 6, it is schematic diagram illustrating the process of collecting the relative position between the sampling position corresponding to the delay stage and the scanning data window center, prior to S1, further comprises:
S0 Scrambling the LVDS differential data, converting them into serial data through parallel-to-serial conversion, and inputting them into delay chain;
After S4, further comprises:
S6 Descrambling and restoring the received LVDS differential data.

Specifically, existing timing training methods support interfaces for dynamically calibrating sampling positions, when there is no effective data in the interface, continuous constant 0/constant 1 data streams may occur, resulting in the failure of window calibration and causing the sampling position to deviate from the data window center. Therefore, at the transmitting terminal of the LVDS transceiver in FIG. 2, LVDS differential data is processed through a scrambling module to perform scrambling. The serialized data is then transmitted to the receiving terminal of the LVDS transceiver via a parallel-to-serial conversion module. At the receiving terminal of the LVDS transceiver, the data outputted from the data path selection module is descrambled using a descrambling module. By scrambling and descrambling, it is avoided that when there is no effective data transmission at the transmitting terminal, the serial data stream will be constant 0/constant 1, which prevents the receiving terminal from performing timing training and window calibration. It can also prevent the inability to effectively obtain the sampling position when there is no effective data for a long time.

In some examples, the smaller the delay stage difference, the smaller the discrepancy in errors on the same chip and the difference in delay stages caused by asymmetry in the P-end and N-end slopes of LVDS differential data.

Specifically, let the first delay step be denoted as “step_path1” and the second delay step as “step_path2”. Then, the offset=step_path1−step_path2 represents the asymmetry between the data on the first path and the second path caused by the asymmetry in slew rates of OCV and LVDS differential data on the P-end and N-end. A smaller offset indicates less asymmetry between the data on the first path and the second path, resulting in smaller errors on the same chip and less difference in delay step caused by the asymmetry in slew rates of LVDS differential data on the P-end and N-end.

In some examples, as shown in FIG. 8, it is shown a block diagram of a timing training apparatus for LVDS interface, the apparatus comprises:
a conversion module 701, which is configured for inputting the P-end of the LVDS differential data signal into the first delay chain, converting it into the first parallel data through serial-to-parallel conversion; inputting the N-end of the LVDS differential data signal into the second delay chain, converting it into the second parallel data through serial-to-parallel conversion;
a first sampling module 702, which is configured for sampling data with the second parallel data as reference data and the first parallel data as scanning data, and collecting the relative position between the sampling position corresponding to the delay stage and the center of the scanning data window, when the sampling position corresponding to the delay stage is located at the center of the scanning data window, recording the current delay stage as the first delay stage;
a second sampling module 703, which is configured for sampling data with the first parallel data as reference data and the second parallel data as scanning data, setting the initial delay stage of the second parallel data the same as the first delay stage, and collecting the relative position between the sampling position corresponding to the delay stage and the center of the scanning data window, and when the sampling position corresponding to the first delay stage is located at the center of the scanning data window, recording the current first delay stage as the second delay stage;
a data output path determination module 704, which is configured for obtaining the delay stage difference through the first delay stage and the second delay stage, setting the sum of the first delay stage and half of the delay stage difference as the delay stage of the first parallel data, and receiving LVDS differential data by using the second parallel data as scanning data.

The specific specifications regarding the timing training apparatus for LVDS interface can be referred in the above description of the method, and are not reiterated here. The various modules in the aforementioned timing training apparatus for LVDS interface can be fully or partially implemented by means of software, hardware, or their combination. These modules can be embedded in hardware within or independent of processors in computing devices, or stored in software form in the memory of computing devices, for ease of execution by processors to perform the corresponding operations of the aforementioned modules.

The above-described embodiments are merely embodiments of the present disclosure. For those skilled in the art, improvements can be made without departing from the concept of the present disclosure, but these improvements all belong to the protection scope of the present disclosure.

1. A method for timing training on an LVDS interface comprising:
inputting the P-end of the LVDS differential data signal into a first delay chain, and converting them into first parallel data through serial-to-parallel conversion; inputting the N-end of the LVDS differential data signal into a second delay chain, and converting them into second parallel data through serial-to-parallel conversion;
sampling by using the second parallel data as reference data and the first parallel data as scanning data, and collecting the relative position between the sampling position corresponding to the current delay stage and the center of the scanning data window, when the sampling position corresponding to the current delay stage is located at the center of the scanning data window, the current delay stage is recorded as the first delay stage;
sampling by using the first parallel data as reference data and the second parallel data as scanning data, and setting the initial delay stage of the second parallel data as the first delay stage, collecting the relative position between the sampling position corresponding to the current delay stage and the center of the scanning data window, when the sampling position corresponding to the current delay stage is located at the center of the scanning data window, the current first delay stage is recorded as the second delay stage;
obtaining the delay stage difference according to the first delay stage and the second delay stage, and setting the sum of the first delay stage and half of the delay stage difference as the delay stage of the first parallel data, receiving the LVDS differential data by using the second parallel data as scanning data.

2. The method as claimed in claim 1, wherein sampling by using the second parallel data as reference data and the first parallel data as scanning data, and collecting the relative position between the sampling position corresponding to the current delay stage and the center of the scanning data window further comprising:
sampling by using the second parallel data as reference data after setting the initial delay stage of the first parallel data, and collecting the relative position corresponding to the initial delay stage, wherein the initial delay stage is less than the total delay stage of the first delay chain;
when the sampling position corresponding to the current initial delay stage is offset to the left relative to the center of the first parallel data window, decreasing the current initial delay stage, and after updating the decreased initial delay stage to the initial delay stage, re-collecting the relative position;
when the sampling position corresponding to the current initial delay stage is offset to the right relative to the center of the first parallel data window, increasing the current initial delay stage, and after updating the increased initial delay stage to the initial delay stage, re-collecting the relative position;
when the sampling position corresponding to the current initial delay stage is located at the center of the first parallel data window, the initial delay stage corresponding to the sampling position is taken as the first delay stage.

3. The method as claimed in claim 2, wherein sampling by using the first parallel data as reference data and the second parallel data as scanning data, and setting the initial delay stage of the second parallel data as the first delay stage, collecting the relative position between the sampling position corresponding to the current delay stage and the center of the scanning data window further comprising:
scanning is conducted using the first parallel data as reference data after setting the first delay stage as the initial delay stage of the second parallel data, whilst collecting the relative position corresponding to the initial delay stage;
when the sampling position corresponding to the current initial delay stage is offset to the left relative to the center of the second parallel data window, decreasing the current initial delay stage, and after updating the decreased initial delay stage to the initial delay stage, re-collecting the relative position;
when the sampling position corresponding to the current initial delay stage is offset to the right relative to the center of the first parallel data window, increasing the current initial delay stage, and after updating the increased initial delay stage to the initial delay stage, re-collecting the relative position;
when the sampling position corresponding to the current initial delay stage is located at the center of the second parallel data window, the initial delay stage corresponding to the sampling position is taken as the second delay stage.

4. The method as claimed in claim 3, wherein collecting the relative position between the sampling position corresponding to the delay stage and the center of the scanning data window further comprising:
selecting one set of data between the first parallel data and the second parallel data as reference data, and the other set of data as scanning data, to collect data, and the current delay stage corresponding to the scanning data in both the first parallel data and the second parallel data is defined as the delay stage of the scanning data;
decreasing the current delay stage step by step, monitoring whether the reference data and the scanning data are consistent during a specific time period;
if the reference data and the scanning data are consistent, and the current delay stage has not decreased to zero, repeating decreasing the current delay stage step by step and monitoring whether the reference data and the scanning data are consistent during a specific time period; otherwise, recording the current delay stage as the first sub-delay stage and proceeding to reload the current delay stage;
increasing the current delay stage step by step, monitoring whether the reference data and the scanning data are consistent during a specific time period;
if the reference data and the scanning are consistent, and the current delay stage has not reached the maximum delay stage value, repeating increasing the current delay stage step by step and monitoring whether the reference data and the scanning data are consistent during a specific time period; otherwise, recording the current delay stage as the second sub-delay stage;
based on the current delay stage, the first sub-delay stage, and the second sub-delay stage, obtaining the first sub-delay stage difference between the current delay stage and the first sub-delay stage, and the second sub-delay stage difference between the current delay stage and the second sub-delay stage; comparison of the first sub-delay stage difference and the second sub-delay stage difference, obtaining the relative position between the sampling position corresponding to the current delay stage and the center of the scanning data window.

5. The method as claimed in claim 4, wherein comparison of the first sub-delay stage difference and the second sub-delay stage difference, obtaining the relative position between the sampling position corresponding to the current delay stage and the center of the scanning data window further comprising:
the difference between the current delay stage and the first sub-delay stage is defined as the first sub-delay stage difference, and the difference between the second sub-delay stage and the current delay stage is defined as the second sub-delay stage difference;
if the first sub-delay stage difference is greater than the second sub-delay stage, then the current sampling position corresponding to the current delay stage is offset to the left relative to the center of the scanning data window in both the first parallel data and the second parallel data;
if the first sub-delay stage difference is less than the second sub-delay stage, then the current sampling position corresponding to the current delay stage is offset to the right relative to the center of the scanning data window in both the first parallel data and the second parallel data;
if the first sub-delay stage difference equals to the second sub-delay stage, then the current sampling position corresponding to the current delay stage is at the center of the scanning data window in both the first parallel data and the second parallel data.

6. The method as claimed in claim 1, wherein the total delay of the first delay chain and the second delay chain is greater than the width of the serial data window.

7. The method as claimed in claim 1, prior to inputting the P-end of the LVDS differential data signal into a first delay chain, and converting them into first parallel data through serial-to-parallel conversion, further comprising:
scrambling the LVDS differential data, converting them into serial data through parallel-to-serial conversion, and inputting them into delay chain;
after receiving the LVDS differential data by using the second parallel data as scanning data, further comprising:
descrambling and restoring the received LVDS differential data.

8. The method as claimed in claim 2, wherein the initial delay stage is half of the total delay stage of the first delay chain.

9. The method as claimed in claim 1, wherein the smaller the delay stage difference, the smaller the discrepancy in errors on the same chip and the difference in delay stages caused by asymmetry in the P-end and N-end slopes of LVDS differential data.

10. An apparatus for timing training on an LVDS interface comprising:
a conversion module, which is configured for inputting the P-end of the LVDS differential data signal into the first delay chain, converting it into the first parallel data through serial-to-parallel conversion; inputting the N-end of the LVDS differential data signal into the second delay chain, converting it into the second parallel data through serial-to-parallel conversion;
a first sampling module, which is configured for sampling data with the second parallel data as reference data and the first parallel data as scanning data, and collecting the relative position between the sampling position corresponding to the delay stage and the center of the scanning data window, when the sampling position corresponding to the delay stage is located at the center of the scanning data window, recording the current delay stage as the first delay stage;
a second sampling module, which is configured for sampling data with the first parallel data as reference data and the second parallel data as scanning data, setting the initial delay stage of the second parallel data the same as the first delay stage, and collecting the relative position between the sampling position corresponding to the delay stage and the center of the scanning data window, and when the sampling position corresponding to the first delay stage is located at the center of the scanning data window, recording the current first delay stage as the second delay stage;
a data output path determination module, which is configured for obtaining the delay stage difference through the first delay stage and the second delay stage, setting the sum of the first delay stage and half of the delay stage difference as the delay stage of the first parallel data, and receiving the LVDS differential data by using the second parallel data as scanning data.
